(19) United States
(12) Patent Application Publication
(10) Pub. No.: US 2024/0268153 A1
(43) Pub. Date: Aug. 8, 2024

(54) DISPLAY DEVICE AND METHOD OF FABRICATING THE SAME

(71) Applicant: Samsung Display Co., LTD., Yongin-si (KR)

(72) Inventors: Mi Hwa LEE, Yongin-si (KR); Hyeo Ji KANG, Yongin-si (KR); Oh Jeong KWON, Yongin-si (KR); Tae Ho KIM, Yongin-si (KR); Hong Yeon LEE, Yongin-si (KR); Sung Gyu JANG, Yongin-si (KR); Seung Yeon JEONG, Yongin-si (KR)

(21) Appl. No.: 18/368,710

(22) Filed: Sep. 15, 2023

(30) Foreign Application Priority Data
Feb. 7, 2023 (KR) 10-2023-0016358

(51) Int. Cl. H10K 59/122; H10K 59/12; H10K 59/35; H10K 59/80

(52) U.S. Cl. CPC H10K 59/122; H10K 59/1201; H10K 59/35; H10K 59/8792

(57) ABSTRACT

A display device includes a first pixel including a first emission area formed to emit light having a first color in a third direction, a second pixel including a second emission area formed to emit light having a second color different from the first color, a first partition wall in which a first opening overlapping the first emission area in a plan view is defined, a second partition wall in which a second opening overlapping the second emission area in the plan view is defined, and a first layer covering the first partition wall and the second partition wall. The first partition may be provided with a first height in the third direction. The second partition wall may be provided with a second height different from the first height.

This application claims priority to Korean patent application number 10-2023-0016358, filed on Feb. 7, 2023, and all the benefits accruing therefrom under 35 U.S.C. § 119, the content of which in its entirety is herein incorporated by reference.

### BACKGROUND

### 1. Field

Various embodiments of the disclosure relate to a display device and a method of fabricating the display device.

### 2. Description of Related Art

Among various types of display devices, display devices including organic light-emitting diodes (“OLEDs”) are being widely used due to various advantageous properties such as low power consumption, high luminance, a high reaction speed, and the like.

### SUMMARY

In display devices including organic light-emitting diodes (“OLEDs”), may be a problem of a white angular dependency (“WAD”) phenomenon resulting from variation in side visual angle. The WAD is a phenomenon in which, when an organic electroluminescent light-emitting diode emits light, white light is expressed on a front surface but other colors of light except white light are expressed on a side surface because the wavelength of light is changed by variation in interference length due to a resonance structure.

Various embodiments of the disclosure are directed to a partition wall capable of enhancing a front light output efficiency to mitigate a WAD phenomenon due to variation in side visual angle.

However, features of the disclosure are not limited to the above-described features, and various modifications are possible without departing from the spirit and scope of the disclosure.

An embodiment of the disclosure may provide a display device including a first pixel including a first emission area formed to emit light having a first color in a third direction, a second pixel including a second emission area formed to emit light having a second color different from the first color, a first partition wall in which a first opening overlapping the first emission area in a plan view is defined, a second partition wall in which a second opening overlapping the second emission area in the plan view is defined, and a first layer covering the first partition wall and the second partition wall. The first partition wall may be provided with a first height in the third direction, and the second partition wall may be provided with a second height different from the first height.

In an embodiment, the light of the first color may include red light. The light of the second color may include green light or blue light. The first height of the first partition wall may be greater than the second height of the second partition wall.

In an embodiment, a ratio of the first height of the first partition wall and the second height of the second partition wall may be about 1:0.3.

In an embodiment, each of the first partition wall and the second partition wall may include a first refractive index. The first layer may include a second refractive index higher than the first refractive index.

In an embodiment, the display device may further include a light-blocking component which defines a non-emission area between the first emission area and the second emission area. The first partition wall and the second partition wall may be disposed in a same layer as the light-blocking component.

In an embodiment, in the plan view, a portion of the first partition wall may directly contact a first side of the light-blocking component, and a portion of the second partition wall may directly contact a second side of the light-blocking component.

In an embodiment, the light-blocking component, the first partition wall, and the second partition wall may be integrally disposed.

In an embodiment, each of the first pixel and the second pixel may include a light-emitting element, a transistor configured to control current of the light-emitting element, and a first inorganic layer covering the light-emitting element. The light-emitting element may include a first electrode, an emission layer disposed on the first electrode, and a second electrode disposed on the emission layer. The first partition wall and the second partition wall may be disposed on the first inorganic layer.

In an embodiment, the display device may further include a pixel defining layer disposed between the light-emitting element of the first pixel and the light-emitting element of the second pixel. In the plan view the pixel defining layer may overlap the light-blocking component.

In an embodiment, the display device may further include an organic layer directly disposed on the first inorganic layer, and a second inorganic layer directly disposed on the organic layer. The first partition wall and the second partition wall may be directly disposed on the second inorganic layer.

In an embodiment, the display device may further include an organic layer directly disposed on the first inorganic layer, a second inorganic layer and a third inorganic layer successively disposed on the organic layer, and a sensing electrode disposed on the second inorganic layer and overlapping the non-emission area in the plan view. The first partition wall and the second partition wall may be directly disposed on the third inorganic layer.

In an embodiment, the display device may further include a third pixel including a third emission area which emits, in the third direction, light having a third color different from the first color or the second color, and a third partition wall in which a third opening overlapping the third emission area in the plan view is defined. The light of the first color may include red light, the light of the second color may include green light, and the light of the third color may include blue light. The third partition wall may be provided with a third height different from the first height. In an embodiment, the first height, the second height, and the third height may be different from each other.

In an embodiment, the third partition wall may include dye capable of absorbing light in a wavelength band ranging from about 380 nanometers (nm) to about 430 nm.

In an embodiment, the first layer may include at least one dye. The maximum absorption wavelength of the first layer may range from about 530 nm to about 600 nm.

In an embodiment, the at least one dye may include at least one of tetraazaporphyrin, porphyrin, oxazine, squarylium, polymethine, triarylmethane, anthraquinone, phtalocyanine, azo, perylene, xanthene, diimmonium, and dipyrromethene.

An embodiment of the disclosure may provide a method of fabricating a display device. The method includes disposing a light-blocking component on a substrate, forming a first organic layer on the light-blocking component, removing a portion of the first organic layer, and forming a first partition wall having a first height and a second partition wall having a second height different from the first height, and forming a second organic layer covering the light-blocking component, the first partition wall, and the second partition wall.

In an embodiment, removing the portion of the first organic layer may include exposing and developing the first organic layer using a half-tone mask, and forming the first partition wall and the second partition wall.

In an embodiment, a portion of the first organic layer that corresponds to a first area of the half-tone mask may be provided as the first partition wall, and a portion of the first organic layer that corresponds to a second area of the half-tone mask may be provided as the second partition wall. A transmittance of the first area may be higher than a transmittance of the second area.

In an embodiment, a height of the first partition wall may be greater than a height of the second partition wall.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a schematic plan view illustrating an embodiment of a display device in accordance with the disclosure.

FIG. 2A is a cross-sectional view illustrating an embodiment of the display device of FIG. 1.

FIG. 2B is a cross-sectional view illustrating another embodiment of the display device of FIG. 1.

FIG. 3 is a circuit diagram illustrating an embodiment of a pixel included in the display device of FIG. 1.

FIG. 4 is a plan view illustrating an embodiment of sensing electrodes included in an input sensing layer of FIG. 2A.

FIG. 5 is a schematic cross-sectional view illustrating a display panel including the input sensing layer taken along line I-I′ and line II-II′ of FIG. 4.

FIG. 6 is a graph showing a comparative example and an embodiment of movement of color coordinates as a function of a visual angle in accordance with the disclosure.

FIG. 7 is a schematic cross-sectional view of a display device (or a display panel) of FIG. 2B.

FIGS. 8 to 12 are cross-sectional views schematically illustrating a method of fabricating the display device in embodiments of the disclosure.

### DETAILED DESCRIPTION

Various embodiments of the disclosure will hereinafter be described in detail with reference to the accompanying drawings. The same reference numerals are used throughout the different drawings to designate the same components, and repetitive description of the same components will be omitted.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” or “approximately” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

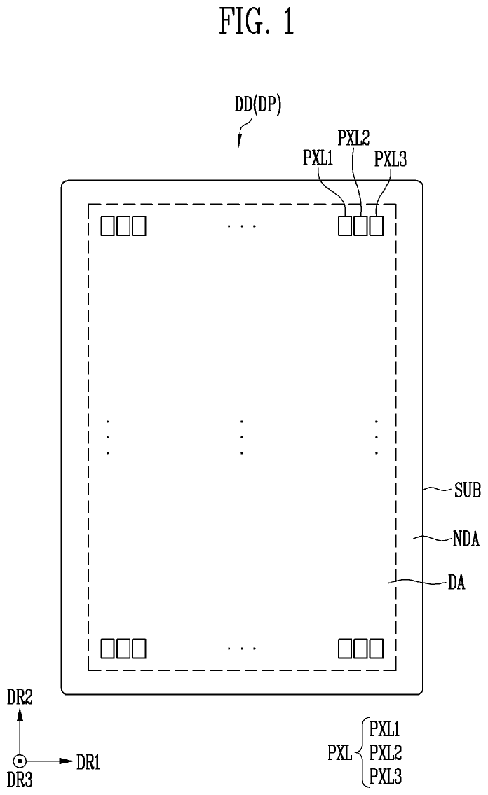

FIG. 1 is a schematic plan view illustrating an embodiment of a display device DD in accordance with the disclosure.

Referring to FIG. 1, a display panel DP (or the display device DD) in an embodiment may be provided in various forms, e.g., in the form of a quadrangular plate, e.g., rectangular plate having two pairs of parallel sides, but the disclosure is not limited thereto. In the case where the display panel DP is provided in the form of a quadrangular plate, e.g., rectangular plate, one pair of sides of the two pairs of sides may be longer than the other.

At least a portion of the display panel DP may have flexibility, and the display panel DP may be folded on the portion having the flexibility, but the disclosure is not limited thereto.

The display panel DP may display an image. A self-emissive display panel, such as an organic light-emitting display panel (“OLED panel”) using an organic light-emitting diode as a light-emitting element, a subminiature light-emitting diode (“LED”) (e.g., micro-LED or nano-LED) display panel using a subminiature LED as a light-emitting element, and a quantum dot OLED panel (“QD OLED panel”) using a quantum dot and an organic light-emitting diode, may be used as the display panel DP. In addition, a non-emissive display panel such as a liquid crystal display (“LCD”) panel, an electro-phoretic display (“EPD”) panel, or an electro-wetting display (“EWD”) panel may be used as the display panel DP. In case that the non-emissive display panel is used as the display panel DP, the display device DD may include a backlight unit configured to supply light to the display panel DP.

The display panel DP may include a substrate SUB, and pixels PXL provided on the substrate SUB.

The substrate SUB may include transparent insulating material to allow light transmission. The substrate SUB may be a rigid substrate or a flexible substrate.

In an embodiment, the rigid substrate may be one of a glass substrate, a quartz substrate, a glass ceramic substrate, and a crystalline glass substrate, for example.

The flexible substrate may be either a film substrate or a plastic substrate which includes polymer organic material. In an embodiment, the flexible substrate SUB may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate, for example.

One area of the substrate SUB may be provided as the display area DA in which the pixels PXL are disposed, and the other area of the substrate SUB may be provided as the non-display area NDA. In an embodiment, the substrate SUB may include a display area DA including a plurality of pixel areas in which the respective pixels PXL are disposed, and a non-display area NDA disposed around the perimeter of the display area DA (or adjacent to the display area DA), for example.

The non-display area NDA may be disposed adjacent to the display area DA. The non-display area NDA may be provided on at least one side of the display area DA. In an embodiment, the non-display area NDA may enclose the perimeter (or edges) of the display area DA, for example. A line component connected to each of the pixels PXL, and a driver connected to the line component and configured to drive the pixel PXL may be provided in the non-display area NDA.

The pixel PXL may include a plurality of pixels. In an embodiment, the pixels PXL may include a first pixel PXL1, a second pixel PXL2, and a third pixel PXL3, for example. The first pixel PXL1, the second pixel PXL2, and the third pixel PXL3 may be successively disposed in a first direction DR1. However, the disclosure is not limited to the foregoing, and the first pixel PXL1, the second pixel PXL2, and the third pixel PXL3 may be successively disposed in a second direction DR2 intersecting the first direction DR1.

The first, second, and third pixels PXL1, PXL2, and PXL3 may emit different colors of light from each other. In an embodiment, the first pixel PXL1 may be a red sub-pixel configured to emit red light, the second pixel PXL2 may be a green sub-pixel configured to emit green light, and the third pixel PXL3 may be a blue sub-pixel configured to emit blue light, for example. However, the colors, types and/or number of pixels forming the pixel PXL are not particularly limited. In an embodiment, the color of light which is emitted from each of the pixels PXL1 to PXL3 may be changed in various ways, for example.

Hereinafter, the term “pixel PXL” will be used to collectively designate the first to third pixels PXL1 to PXL3.

The pixel PXL may include a plurality of pixels PXL which are arranged in a matrix form along rows extending in the first direction DR1 and columns extending in the second direction DR2. The arrangement of the pixels PXL is not limited to a predetermined example. In the case where the pixel PXL is provided in a plural number, the pixels PXL may have different surface areas (or sizes) from each other. In an embodiment, in the case in which the pixels PXL emit different colors of light from each other, the pixels PXL may have different surface areas (or different sizes) or different shapes by colors from each other, for example.

The driver may provide a signal and a power voltage to each pixel PXL through the line component to control the operation of the pixel PXL.

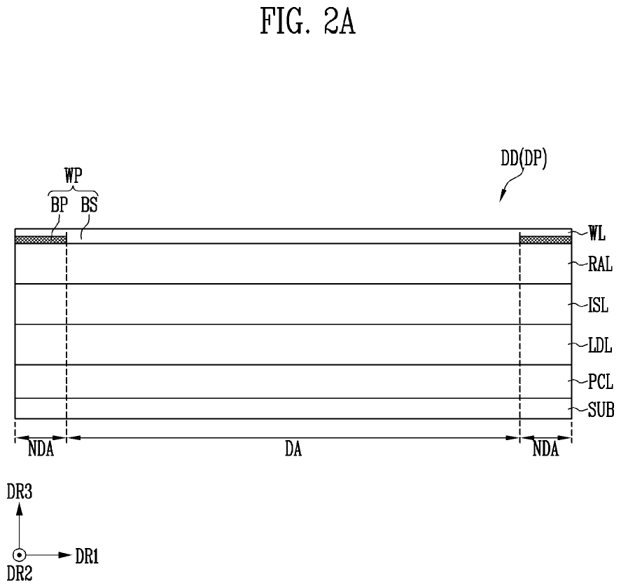

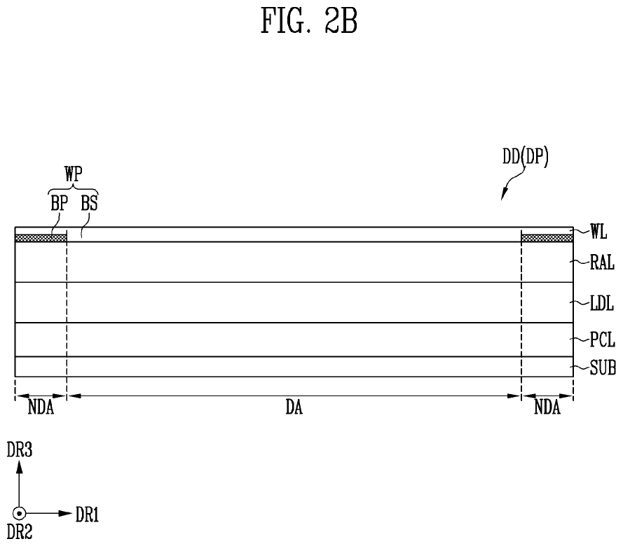

FIG. 2A is a cross-sectional view illustrating an embodiment of the display device DD of FIG. 1. FIG. 2B is a cross-sectional view illustrating another embodiment of the display device DD of FIG. 1.

FIGS. 2A and 2B are for describing a stacked relationship of functional panels and/or functional units which form the display device DD.

Referring to FIG. 2A, the display device DD (or each of the pixels PXL) may include a pixel circuit layer PCL disposed on the substrate SUB, a display element layer LDL, an input sensing layer (or an input sensing panel) ISL, a reflection adjusting layer RAL, and a window layer WL.

The pixel circuit layer PCL may be provided on the substrate SUB, and include a plurality of transistors and signal lines connected to the transistors. In an embodiment, each transistor may have a shape in which a semiconductor pattern, a gate electrode, a source electrode, and a drain electrode are successively stacked with insulating layers interposed therebetween, for example. The semiconductor pattern may include amorphous silicon, poly silicon, relatively low temperature poly silicon, and an organic semiconductor, and/or an oxide semiconductor. Although the gate electrode, the source electrode, and the drain electrode each may include at least one of aluminum (Al), copper (Cu), titanium (Ti), and molybdenum (Mo), the disclosure is not limited thereto. In addition, the pixel circuit layer PCL may include at least one or more insulating layers.

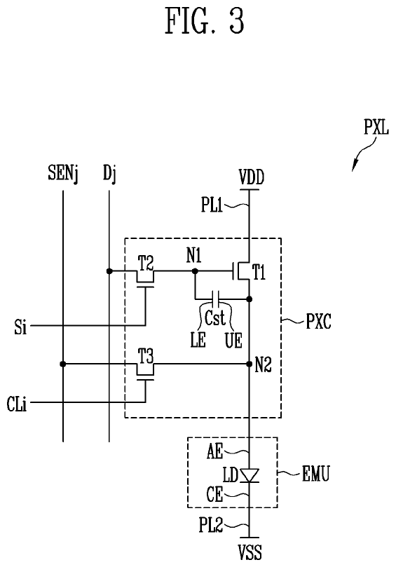

The display element layer LDL may be disposed on the pixel circuit layer PCL. The display element layer LDL may include a light-emitting element (e.g., refer to a light-emitting element LD of FIGS. 3, 5 and 7) configured to emit light. Although the light-emitting element may be, e.g., an organic light-emitting diode, the disclosure is not limited thereto. In an embodiment, the light-emitting element may be an inorganic light-emitting element including inorganic light-emitting material, or a light-emitting element that emits light after changing the wavelength of the light to be emitted using quantum dots.

The display element layer LDL may selectively include an encapsulation film. The encapsulation film may be an encapsulation substrate or be provided in the form of a multilayer film. The encapsulation film may include an inorganic layer and/or an organic layer. In an embodiment, the encapsulation film may have a structure formed by successively stacking an inorganic layer, an organic layer, and an inorganic layer, for example. The encapsulation film may prevent external air or water from permeating the light-emitting element or the pixel circuit layer PCL.

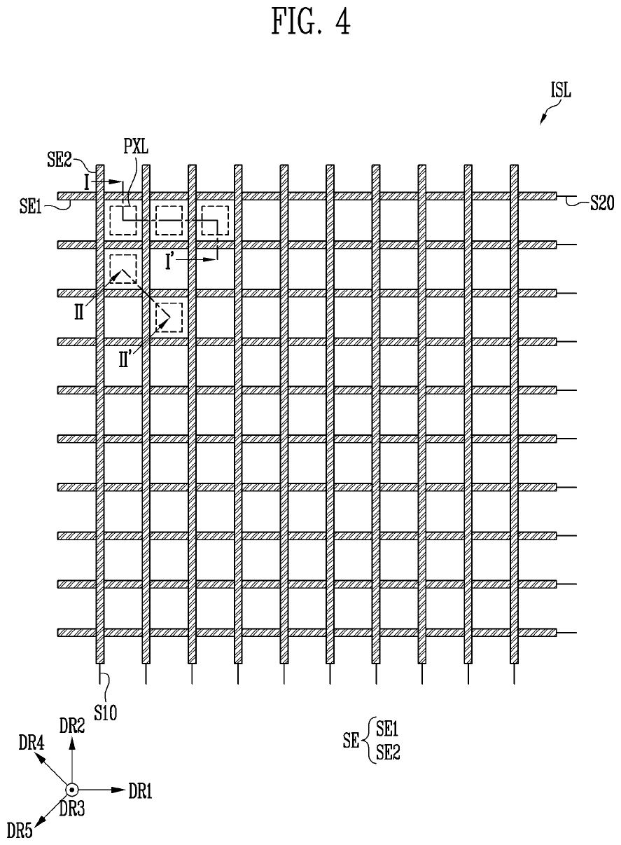

The input sensing layer ISL may be disposed on the display element layer LDL. The input sensing layer ISL may sense contact or input from an external medium such as the hand of a user or a stylus pen on the display area DA of the display device DD. Light emitted from the display element layer LDL may pass through the input sensing layer ISL. The input sensing layer ISL will be described below with reference to FIG. 4.

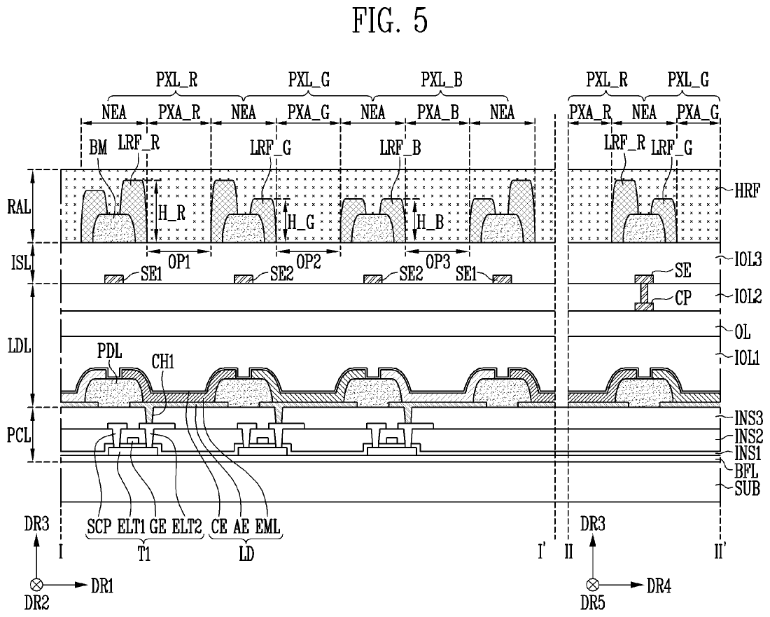

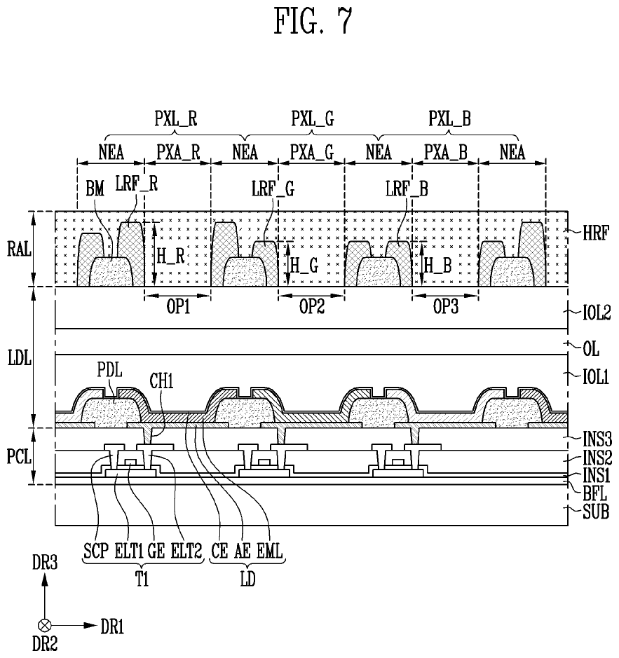

The reflection adjusting layer RAL may be disposed on the input sensing layer ISL. The reflection adjusting layer RAL may block external light from being incident into the display device DD, and allows light emitted from the display element layer LDL to be emitted through the display area DA of the display device DD. The reflection adjusting layer RAL will be described with reference to FIGS. 5 and 7.

Although an embodiment in which the input sensing layer ISL overlaps the entirety of the display element layer LDL is illustrated in FIG. 2A, the foregoing is only for illustrative purposes. The input sensing layer ISL may overlap only a portion of the display area DA or only the non-display area NDA. The input sensing layer ISL may be a touch sensing layer (or a touch sensing panel) configured to sense a touch form the user.

The window layer WL may be disposed on the reflection adjusting layer RAL. The window layer WL may be disposed to cover a front surface of the display device DD (or the display panel DP). The window layer WL may protect the front surface of the display device DD (or the display panel DP). The window layer WL may be attached on the reflection adjusting layer RAL by an adhesive. The adhesive may include at least one of optical clear adhesive (“OCA”) or a pressure sensitive adhesive (“PSA”). However, the disclosure is not limited thereto.

The window layer WL may include a window panel WP. The window panel WP may include a base film BS and a light-blocking pattern BP. The base film BS may have relatively high transmittance to allow light emitted from the display element layer LDL to pass therethrough, and may have a relatively small thickness to minimize the weight of the display device DD (or the display panel DP). Furthermore, the base film BS may have relatively high strength and hardness to protect the display device DD (or the display panel DP) from external shocks. In an embodiment, the base film BS may include or consist of glass. The base film BS may include or consist of ultra thin glass (“UTG”) which is enhanced in strength by a method such as a chemical reinforcement method or a thermal reinforcement method. However, the disclosure is not limited thereto. The base film BS may be a flexible window. The base film BS may easily bend in response to external force without cracking, and thus protect the display device DD (or the display panel DP). The light-blocking pattern BP may partially overlap the base film BS. The light-blocking pattern BP may be disposed on a rear surface of the base film BS, and may define a bezel area of the display device DD, i.e., the non-display area NDA of the display device DD.

Referring to FIG. 2B, the display device DD may not include the input sensing layer ISL. In the display device DD in an embodiment, the display element layer LDL, the reflection adjusting layer RAL, and the window layer WL may be successively disposed on the substrate SUB. In an embodiment, the reflection adjusting layer RAL may be disposed on the display element layer LDL.

FIG. 3 is a circuit diagram illustrating an embodiment of a pixel PXL included in the display device DD of FIG. 1.

For the sake of explanation, FIG. 3 illustrates a pixel PXL disposed on an i-th pixel row (or an i-th horizontal line) and a j-th pixel column (where each of i and j is a natural number).

Referring to FIGS. 1 to 3, the pixel PXL may include an emission component EMU configured to generate light having a luminance corresponding to a data signal. Furthermore, the pixel PXL may further include a pixel circuit PXC configured to drive the emission component EMU.

The emission component EMU may include a light-emitting element LD connected between a first power line PL1 provided to receive a voltage from a first driving power supply (or a first power supply) VDD and a second power line PL2 provided to receive a voltage from a second driving power supply (or a second power supply) VSS. In an embodiment, the emission component EMU may include the light-emitting element LD which include a first electrode AE connected to the first driving power supply VDD via the first power line PL1, and a second electrode CE connected to the second driving power supply VSS via the second power line PL2, for example. The first electrode AE may be an anode, and the second electrode CE may be a cathode. The first driving power supply VDD and the second driving power supply VSS may have different potentials from each other. Here, a difference in potential between the first and second driving power supplies VDD and VSS may be set to a value equal to or greater than a threshold voltage of the light-emitting element LD during an emission period of the pixel PXL.

In the case in which the pixel PXL is disposed on an i-th pixel row and a j-th pixel column in the display area DA, the pixel circuit PXC of the pixel PXL (or the sub-pixel) may be electrically connected to an i-th scan line Si and a j-th data line Dj. Furthermore, the pixel circuit PXC may be electrically connected to an i-th control line CLi and a j-th sensing line SENj.

The pixel circuit PXC may include first to third transistors T1, T2, and T3, and a storage capacitor Cst.

The first transistor T1 may be a driving transistor configured to control driving current to be applied to the light-emitting element LD and be electrically connected between the first driving power supply VDD and the light-emitting element LD. In detail, a first terminal of the first transistor T1 may be electrically connected to the first driving power supply VDD by the first power line PL1. A second terminal of the first transistor T1 may be electrically connected to a second node N2. A gate electrode of the first transistor T1 may be electrically connected to a first node N1. The first transistor T1 may control, in response to a voltage applied to the first node N1, driving current to be applied from the first driving power supply VDD to the light-emitting element LD through the second node N2. In an embodiment, the first terminal of the first transistor T1 may be a drain electrode, and the second terminal of the first transistor T1 may be a source electrode, and the disclosure is not limited thereto. In an embodiment, the first terminal may be a source electrode, and the second terminal may be a drain electrode.

The second transistor T2 may be a switching transistor configured to select a pixel PXL in response to a scan signal and activate the pixel PXL, and may be electrically connected between the data line Dj (e.g., a j-th data line) and the first node N1. A first terminal of the second transistor T2 may be electrically connected to the data line Dj. A second terminal of the second transistor T2 may be electrically connected to the first node N1 (or the gate electrode of the first transistor T1). A gate electrode of the second transistor T2 may be electrically connected to the scan line Si (or the i-th scan line). The first terminal and the second terminal of the second transistor T2 are different terminals, and when the first terminal is a drain electrode, for example, the second terminal may be a source electrode.

When a scan signal having a gate-on voltage (e.g., a relatively high level voltage) is supplied from the scan line Si, the second transistor T2 may be turned on to electrically connect the data line Dj with the first node N1. The first node N1 may be a point at which the second terminal of the second transistor T2 and the gate electrode of the first transistor T1 are connected to each other. The second transistor T2 may transmit a data signal to the gate electrode of the first transistor T1.

The third transistor T3 may obtain a sensing signal through the j-th sensing line (hereinafter also referred to as a sensing line for convenience) SENj by electrically connecting the first transistor T1 to the sensing line SENj, and detect, using the sensing signal, characteristics of the pixel PXL such as a threshold voltage of the first transistor T1. Information about the characteristics of the pixel PXL may be used to convert image data such that a deviation in characteristic between pixels PXL may be compensated for. A second terminal of the third transistor T3 may be electrically connected to the second terminal of the first transistor T1. A first terminal of the third transistor T3 may be electrically connected to the sensing line SENj. A gate electrode of the third transistor T3 may be electrically connected to the control line CLi (e.g., the i-th control line). The first terminal may be a drain electrode, and the second terminal may be a source electrode.

The third transistor T3 may be an initialization transistor configured to initialize the second node N2, and may be turned on when a sensing control signal is supplied thereto from the control line CLi, so that the voltage of the initialization power supply may be transmitted to the second node N2. Hence, the storage capacitor Cst which is electrically connected to the second node N2 may be initialized.

The storage capacitor Cst may include a lower electrode (or a first storage electrode) LE and an upper electrode (or a second storage electrode) UE. The lower electrode LE may be electrically connected to the first node N1. The upper electrode UE may be electrically connected to the second node N2. The storage capacitor Cst may be charged with a data voltage corresponding to a data signal to be supplied to the first node N1 during one frame period. Hence, the storage capacitor Cst may store a voltage corresponding to a difference between a voltage of the gate electrode of the first transistor T1 and a voltage of the second node N2.

Although FIG. 3 illustrates an embodiment where all of the first to third transistors T1, T2, and T3 are N-type transistors, the disclosure is not limited thereto. In an embodiment, at least one of the first to third transistors T1, T2, and T3 may be changed to a P-type transistor, for example.

The structure of the pixel circuit PXC may be changed in various ways.

In the following embodiments, for convenience of explanation, a transverse direction (or an X-axis direction or a horizontal direction) in a plan view will be indicated by the first direction DR1, a longitudinal direction (or a Y-axis direction or a vertical direction) in a plan view will be indicated by the second direction DR2, and a vertical direction in a cross-sectional view will be indicated by a third direction DR3.

FIG. 4 is a plan view illustrating an embodiment of sensing electrodes included in the input sensing layer ISL of FIG. 2A.

Referring to FIG. 4, the input sensing layer ISL may include at least one sensing electrode SE configured to detect whether a touch is present, coordinates of the touch, or the like.

The sensing electrode SE may include a first sensing electrode SE1 extending in the first direction DR1, and a second sensing electrode SE2 extending in the second direction DR2 intersecting with the first direction DR1.

The first sensing electrode SE1 and the second sensing electrode SE2 may be disposed in a shape to enclose a plurality of pixels PXL in a plan view. However, the disclosure is not limited to the foregoing. The first sensing electrode SE1 and the second sensing electrode SE2 may be disposed in a shape to enclose at least one pixel PXL in a plan view. Depending on the density of the first sensing electrode SE1 and the second sensing electrode SE2, the accuracy of touch sensing may be changed.

Although there is illustrated the case where the first sensing electrode SE1 and the second sensing electrode SE2 form a mesh electrode structure, the disclosure is not limited thereto. Each of the first sensing electrode SE1 and the second sensing electrode SE2 may have a surface electrode structure.

The pitches of the first and second sensing electrodes and the widths of the sensing electrodes may be changed depending on the use purpose of the input sensing layer ISL.

The first and second sensing electrodes SE1 and SE2 may include metal or transparent conductive oxide (“TCO”). The transparent conductive oxide (“TCO”) may include at least one of indium tin oxide (“ITO”), indium zinc oxide (“IZO”), zinc oxide (ZnO), carbon nanotube (“CNT”), and graphene.

The first sensing electrode SE1 may be electrically connected to a first line S10. The second sensing electrode SE2 may be electrically connected to a second line S20. The first line S10 and the second line S20 may be connected to a touch driver (not illustrated). The touch driver may input a driving signal to the first sensing electrode SE1, and determine whether a touch is and coordinates of the touch, using capacitance variance or voltage variance which is measured on the second sensing electrode SE2. The touch driver may be directly disposed on a substrate in the form of an integrated circuit (“IC”), or may be provided as a separate component.

FIG. 5 is a schematic cross-sectional view illustrating the display panel DP including the input sensing layer ISL taken along line I-I′ mainly extending in the first direction DR1 and line II-II′ mainly extending in a fourth direction DR4 of FIG. 4. In an embodiment, a fifth direction DR5 may be a direction perpendicular to the fourth direction DR4.

Referring to FIGS. 1 and 5, the display device DD (or the display panel DP) may include first to third pixels PXL_R to PXL_B. The first to third pixels PXL_R to PXL_B illustrated in FIG. 5 may correspond to the first to third pixels PXL1 to PXL3 illustrated in FIG. 1.

The first pixel PXL_R may include a first emission area PXA_R and a non-emission area NEA which encloses the first emission area PXA_R. The second pixel PXL_G may include a second emission area PXA_G and a non-emission area NEA which encloses the second emission area PXA_G. The third pixel PXL_B may include a third emission area PXA_B and a non-emission area NEA which encloses the third emission area PXA_B.

The first to third pixels PXL_R to PXL_B may emit different colors of light from each other. In an embodiment, the first pixel PXL_R may emit a first color of light. The second pixel PXL_G may emit light having a second color different from the first color. The third pixel PXL_B may emit light having a third color different from the first color or the second color. In an embodiment, the first pixel PXL_R may be a red pixel configured to emit red light, for example. The second pixel PXL_G may be a green pixel configured to emit green light. The third pixel PXL_B may be a blue pixel configured to emit blue light.

Referring to FIG. 5, the display device may include a substrate SUB, a pixel circuit layer PCL, an input sensing layer ISL, and a reflection adjusting layer RAL.

The pixel circuit layer PCL may be disposed on the substrate SUB. The pixel circuit layer PCL may include a buffer layer BFL, a first transistor T1, and at least one or more insulating layers INS1 to INS3. At least one or more insulating layers may be disposed on the substrate SUB. In an embodiment, the buffer layer BFL and the first to third insulating layers INS1 to INS3 may be successively stacked on the substrate SUB in the third direction DR3, for example.

The buffer layer BFL may prevent impurities from being diffused into the first transistor T1 provided on the substrate SUB, and may enhance planarization of the substrate SUB. The buffer layer BFL may be provided in the form of a single layer structure, or provided in the form of a multilayer structure. The buffer layer BFL may be an inorganic insulating layer including inorganic material. The inorganic insulating layer may include at least one of metal oxides such as silicon nitride (SiNₓ), silicon oxide (SiOₓ), silicon oxynitride (SiON), and aluminum oxide (AlOₓ), for example. In the case where the buffer layer BFL is provided in the form of a multilayer structure, the respective layers may include or consist of the same material as each other or different materials from each other. The buffer layer BFL may be omitted in some cases.

The first transistor T1 may include a semiconductor pattern SCP, a gate electrode GE, a first terminal ELT1, and a second terminal ELT2. The first terminal ELT1 may be either a source electrode or a drain electrode, and the second terminal ELT2 may be the other electrode. In an embodiment, in the case in which the first terminal ELT1 is a drain electrode, the second terminal ELT2 may be a source electrode, for example.

The semiconductor pattern SCP may be provided and/or formed on the buffer layer BFL. The semiconductor pattern SCP may include a first area which contacts the first terminal ELT1, and a second area which contacts the second terminal ELT2. An area between the first area and the second area may be a channel area. The channel area may overlap the gate electrode GE of the first transistor T1. The semiconductor pattern SCP may be a semiconductor pattern including or consisting of amorphous silicon, polysilicon, low-temperature polysilicon, an oxide semiconductor, an organic semiconductor, or the like. In an embodiment, the channel area may be a semiconductor pattern undoped with impurities and be an intrinsic semiconductor, for example. Each of the first contact area and the second contact area may be a semiconductor pattern doped with impurities.

The first insulating layer (or a gate insulating layer) INS1 may be provided and/or formed on the semiconductor pattern SCP. The first insulating layer INS1 may be an inorganic insulating layer including inorganic material. The first insulating layer INS1 may include the same material as that of the buffer layer BFL, or may include at least one material selected from among the materials exemplified as the constituent materials of the buffer layer BFL. In an embodiment, the first insulating layer INS1 may include or consist of an organic insulating layer including organic material. Although the first insulating layer INS1 may have a single-layer structure, the first insulating layer INS1 may have a multilayer structure having at least two or more layers.

The gate electrode GE may be provided and/or formed on the first insulating layer INS1 to correspond to the channel area of the semiconductor pattern SCP. The gate electrode GE may be provided on the first insulating layer INS1 and overlap the channel area of the semiconductor pattern SCP. The gate electrode GE may have a single layer structure including or consisting of one or combination selected from the group including copper (Cu), molybdenum (Mo), tungsten (W), aluminum neodymium (AlNd), titanium (Ti), aluminum (Al), silver (Ag), and any alloys thereof, or may have a double layer or multilayer structure including or consisting of molybdenum (Mo), titanium (Ti), copper (Cu), aluminum (AI), or silver (Ag) to reduce line resistance.

The second insulating layer (or an inter-insulating layer) INS2 may be provided and/or formed on the gate electrode GE. The second insulating layer INS2 may include the same material as that of the first insulating layer INS1, or may include one or more materials selected from among materials exemplified as the constituent material of the first insulating layer INS1.

The first terminal ELT1 and the second terminal ELT2 may be provided and/or formed on the second insulating layer INS2, and may respectively contact the first area and the second area of the semiconductor pattern SCP through contact holes passing through the first insulating layer INS1 and the second insulating layer INS2. Each of the first and second terminals ELT1 and ELT2 may include the same material as that of the gate electrode GE, or include one or more materials selected from among materials exemplified as the material for forming the gate electrode GE.

Although in the foregoing embodiment the first and second terminals ELT1 and ELT2 of the first transistor T1 each have been described as being a separate electrode electrically connected to the semiconductor pattern SCP through the contact hole that successively passes through the first insulating layer INS1 and the second insulating layer INS2, the disclosure is not limited thereto. In an embodiment, the first terminal ELT1 of the first transistor T1 may be the first area adjacent to the channel area of the corresponding semiconductor pattern SCP. The second terminal ELT2 of the first transistor T1 may be the second area adjacent to the channel area of the corresponding semiconductor pattern SCP. In this case, the first terminal ELT1 of the first transistor T1 may be electrically connected to the light-emitting elements LD through a separate connector such as a bridge electrode.

The third insulating layer (or a passivation layer) INS3 may be provided and/or formed on the first transistor T1. The third insulating layer INS3 may be provided in the form of an organic insulating layer, an inorganic insulating layer, or a structure including an organic insulating layer disposed on an inorganic insulating layer. The inorganic insulating layer may include at least one of silicon oxide (SiOₓ), silicon nitride (SiNx), silicon oxynitride (SiOₓN_{y}), and metal oxide such as aluminum oxide (AlOₓ), for example. The organic insulating layer may include at least one of polyacrylate resin, epoxy resin, phenolic resin, polyamide resin, polyimide rein, unsaturated polyester resin, poly-phenylen ether resin, poly-phenylene sulfide resin, and benzocyclobutene resin, for example.

A first contact hole CH1 through which the second terminal ELT2 of the first transistor T1 is exposed may be defined in the third insulating layer INS3.

The display element layer LDL may be provided on the third insulating layer INS3. The display element layer LDL may include a pixel defining layer PDL, a light-emitting element LD, and encapsulation layers IOL1, IOL2, and OL.

The light-emitting element LD may be provided in various shapes. In the specification, for convenience of explanation, the light-emitting element LD will be described based on an embodiment in which the light-emitting element LD is an organic light-emitting diode (“OLED”).

The light-emitting element LD may be disposed on the pixel circuit layer PCL. In an embodiment, the light-emitting element LD may include a first electrode AE, an emission layer EML, and a second electrode CE.

The first electrode AE may be disposed on the third insulating layer INS3. The first electrode AE may be electrically connected to the second terminal ELT2 through the first contact hole CH1.

The pixel defining layer PDL may be disposed on the pixel circuit layer PCL, and may define a position at which the emission layer EML is to be disposed. The pixel defining layer PDL may be disposed on an exposed surface of the first electrode AE. At least a portion of the first electrode AE may be exposed through an area defined by the pixel defining layer PDL. The pixel defining layer PDL may include organic material. In an embodiment, the pixel defining layer PDL may include or consist of one or more selected from the group including acryl resin, epoxy resin, phenol resin, polyamide resin, and polyimide resin. However, the disclosure is not limited thereto.

In an embodiment, the emission layer EML may be disposed in an area defined by the pixel defining layer PDL. One surface of the emission layer EML may be electrically connected to the first electrode AE. The other surface of the emission layer EML may be electrically connected to the second electrode CE.

The second electrode CE may be disposed on the emission layer EML. The second electrode CE may cover an overall surface of the pixel defining layer PDL, but is not limited thereto. In an embodiment, the second electrode CE may cover the emission layer EML, and may be disposed to cover only a portion of the pixel defining layer PDL, for example.

The first electrode AE may be an anode electrode for the emission layer EML. The second electrode CE may be a common electrode (or a cathode electrode) for the emission layer EML. In an embodiment, the first electrode AE and the second electrode CE may include conductive material. In an embodiment, the first electrode AE may include conductive material having reflectibility, and the second electrode CE may include transparent conductive material, for example, but the disclosure is not limited thereto.

The emission layer EML may have a multilayer thin-film structure including a light generation layer. The emission layer EML may include a hole injection layer into which holes are injected, a hole transport layer which has excellent hole transportation performance and restrains movement of electrons that have not been coupled with holes in the light generation layer and thus increases chances of recombination between holes and electrons, the light generation layer which emits light by recombination between injected electrons and holes, a hole blocking layer which restrains movement of holes that have not been coupled with electrons in the light generation layer, an electron transport layer which is provided to smoothly transport electrons to the light generation layer, and an electron injection layer into which electrons are injected. The emission layer EML may emit light based on an electrical signal which is provided from the first electrode AE and the second electrode CE.

In the case where the first pixel PXL_R is a red pixel, the light-emitting element LD of the first pixel PXL_R may include a red emission layer EML. In the case where the second pixel PXL_G is a green pixel, the light-emitting element LD of the second pixel PXL_G may include a green emission layer EML. In the case where the third pixel PXL_B is a blue pixel, the light-emitting element LD of the third pixel PXL_B may include a blue emission layer EML. However, the disclosure is not limited to the foregoing. In the case where the first to third pixels PXL_R to PXL_B are pixels configured to emit cyan, magenta, and yellow, each pixel may include an emission layer EML configured to emit a corresponding color of light.

In the case where the light-emitting element LD is a top-emission-type light-emitting element, the first electrode AE may be a reflective electrode, and the second electrode CE may be a transmissive electrode or a transflective electrode. In the case where the light-emitting element LD is a bottom-emission-type light-emitting element, the first electrode AE may be a transmissive electrode or a transflective electrode, and the second electrode CE may be a reflective electrode. The light-emitting element LD in an embodiment of the disclosure may be a top-emission-type light-emitting element, the first electrode AE may be a reflective electrode, and the second electrode CE may be a transmissive electrode or a transflective electrode.

The encapsulation layers IOL1, IOL2, and OL may be disposed on the second electrode CE. The encapsulation layers IOL1, IOL2, and OL may prevent water or external air such as oxygen from permeating the light-emitting element LD, and may offset a step difference formed by the light-emitting element LD and the pixel defining layer PDL. Although the encapsulation layers IOL1, IOL2, and OL include two inorganic layers IOL1 and IOL2 and one organic layer OL, the disclosure is not limited thereto.

Each of the first and second inorganic layers IOL1 and IOL2 may be an inorganic insulating layer including inorganic material. The first and second inorganic layers IOL1 and IOL2 may be formed by a chemical vapor deposition (“CVD”) method or an atomic layer deposition (“ALD”) method. However, embodiments of the disclosure are not limited to the foregoing. The organic layer OL may be an organic insulating layer including organic material.

The input sensing layer ISL may be disposed on the display element layer LDL. The input sensing layer ISL may include first and second sensing electrodes SE1 and SE2 and a third inorganic layer IOL3.

The first and second sensing electrodes SE1 and SE2 may be disposed on the second inorganic layer IOL2. Although the first sensing electrode SE1 and the second sensing electrode SE2 are illustrated as being disposed in the same layer, the first and second sensing electrodes SE1 and SE2 may be disposed in different layers.

The third inorganic layer IOL3 may be provided and/or formed on the first and second sensing electrodes SE1 and SE2. The third inorganic IOL3 may be an inorganic insulating layer including inorganic material.

The reflection adjusting layer RAL may be disposed on the input sensing layer ISL. The reflection adjusting layer RAL may include a light-blocking component BM, first to third partition walls LRF_R to LRF_B, and a first layer HRF.

A connector CP may be disposed on the organic layer OL. The connector CP may connect the sensing electrodes SE to each other. Although the connector CP is illustrated as being disposed on the organic layer OL, the disclosure is not limited thereto. The connector CP may be disposed on a separate inorganic layer formed on the organic layer OL. In an embodiment, the connector CP may include a connector provided to connect the first sensing electrodes SE1 to each other, and a connector provided to connect the second sensing electrodes SE2 to each other.

The light-blocking component BM may be provided and/or formed on the third inorganic layer IOL3.

The light-blocking component BM may block external light from being incident into the display device (e.g., by absorbing the external light). The light-blocking component BM may have substantially opaque color. In an embodiment, the light-blocking component BM may further include light-blocking material to absorb light, for example. The light-blocking material may include carbon black, titanium oxynitride, titanium black, phenylene block, aniline black, cyanin block nigrosine acid black, black resin, or the like.

The light-blocking component BM may be disposed in an area overlapping the non-emission area NEA, in a plan view. In an embodiment, the light-blocking component BM may be disposed in an area overlapping the pixel defining layer PDL. The light-blocking component BM may have a mesh pattern or a mesh structure in the same manner as that of the first and second sensing electrodes SE1 and SE2, or an opening corresponding to the opening that is defined by the pixel defining layer PDL may be defined in the light-blocking component BM. The light-blocking component BM may not overlap the opening that is defined by the pixel defining layer PDL.

The opening of the light-blocking component BM may be greater than or identical to the opening of the pixel defining layer PDL. In an embodiment, a surface area of the opening of the light-blocking component BM may be greater than that of the opening of the pixel defining layer PDL, for example. A width of the light-blocking component BM between the pixels in a plan view may be less than that of the pixel defining layer PDL.

The first to third partition walls LRF_R to LRF_B may be disposed on the third inorganic layer IOL3. Each of the first to third partition walls LRF_R to LRF_B may be disposed in an area overlapping the non-emission area NEA.

In an embodiment, the first pixel PXL_R may include the first partition wall LRF_R. A first opening OP1 may be defined in the first partition wall LRF_R. The first opening OP1 may overlap the first emission area PXA_R in a plan view.

The second pixel PXL_G may include the second partition wall LRF_G. A second opening OP2 may be defined in the second partition wall LRF_G. The second opening OP2 may overlap the second emission area PXA_G in a plan view.

The third pixel PXL_B may include the third partition wall LRF_B. A third opening OP3 may be defined in the third pixel PXL_B. The third opening OP3 may overlap the third emission area PXA_B in a plan view.

The first to third partition walls LRF_R to LRF_B may be disposed to protrude in the third direction DR3. Although each of the first to third partition walls LRF_R to LRF_B has a trapezoidal cross-sectional shape, the disclosure is not limited thereto. The first to third partition walls LRF_R to LRF_B may have a cross-sectional shape of a semi-circle, an ellipse, or the like.

In an embodiment, a portion of each of the first to third partition walls LRF_R to LRF_B may overlap the light-blocking component BM in a plan view. The first partition wall LRF_R may be disposed to overlap one side of the light-blocking component BM. The second partition wall LRF_G that is adjacent to the first pixel PXL_R may be disposed to overlap the other side of the light-blocking component BM. The second partition wall LRF_G that is adjacent to the third pixel PXL_B may be disposed to overlap one side of another light-blocking component BM. The third partition wall LRF_B that is adjacent to the second pixel PXL_G may be disposed to overlap the other side of the another light-blocking component BM.

In an embodiment, the first to third partition walls LRF_R to LRF_B may be integrally provided and/or formed with the light-blocking component BM. In this case, the first to third partition walls LRF_R to LRF_B may include at least one of organic light-blocking material, black pigment, and black dye.

The first layer HRF may be disposed on overall surfaces of the light-blocking component BM and the first to third partition walls LRF_R to LRF_B. In an embodiment, a refractive index of the first layer HRF may be higher than that of the first to third partition walls LRF_R to LRF_B. In an embodiment, a difference in refractive index between the first layer HRF and the first to third partition walls LRF_R to LRF_B may be approximately 0.1 or more.

In an embodiment, the first layer HRF may include organic material. In an embodiment, the first layer HRF may include or consist of a single layer structure including organic material such as acrylic resin, epoxy resin, phenol resin, polyamide resin, and polyimide resin, for example, but is not limited thereto so long as the organic material has a refractive index higher than that of the first to third partition walls LRF_R to LRF_B.

The first layer HRF may include at least one dye. The at least one dye may include at least one of tetraazaporphyrin, porphyrin, oxazine, squarylium, polymethine, triarylmethane, anthraquinone, phtalocyanine, azo, perylene, xanthene, diimmonium, and dipyrromethene.

In an embodiment, a functional group of a compound included in the first layer HRF may affect an absorption wavelength range of the compound. Therefore, the respective maximum absorption wavelength ranges of dyes having different functional groups may differ from each other. In an embodiment, the maximum absorption wavelength range of the first layer HRF may range from approximately 530 nanometers (nm) to approximately 600 nm, for example.

Light emitted from the light-emitting element LD included in each of the first to third pixels PXL_R to PXL_B may pass through the first and second inorganic layers IOL1 and IOL2, the organic layer OL, and the input sensing layer ISL.

Light emitted from the light-emitting element LD in the first pixel PXL_R may pass through the first opening OP1 of the first partition wall LRF_R. Light emitted from the light-emitting element LD in the second pixel PXL_G may pass through the second opening OP2 of the second partition wall LRF_G. Light emitted from the light-emitting element LD in the third pixel PXL_B may pass through the third opening OP3 of the third partition wall LRF_B.

Some of the light emitted from the light-emitting element LD included in each of the first to third pixels PXL_R to PXL_B may pass through the first and second inorganic layers IOL1 and IOL2, the organic layer OL, and the input sensing layer ISL, and may be incident on the first layer HRF in a direction tilted slightly with respect to the third direction DR3.

Light rays that are incident on the first layer HRF in a direction tilted slightly among light rays emitted from the light-emitting element LD included in each of the first to third pixels PXL_R to PXL_B may be irradiated onto the first to third partition walls LRF_R to LRF_B, and may be reflected by the first to third partition walls LRF_R to LRF_B due to a refractive index difference (or a refractive index ratio) between the first layer HRF and the first to third partition walls LRF_R to LRF_B, and then be re-incident on the first layer HRF. Some of the light rays that are incident on the first layer HRF in a direction tilted slightly may be totally reflected by the first to third partition walls LRF_R to LRF_B and then emitted in the third direction (or a frontal direction) DR3. Remaining some of the light rays that are incident on the first layer HRF in a direction tilted slightly may be only partially reflected by the first to third partition walls LRF_R to LRF_B and then emitted in a direction (or sideways) other than the third direction DR3. In other words, orientation of only some of the light rays that are incident on the first layer HRF in a direction tilted slightly may be converted in the third direction DR3 (the frontal direction) before the some of the light rays are emitted to the outside.

In an embodiment, the first to third partition walls LRF_R to LRF_B may be structures for controlling paths of the light rays that are incident on the first layer HRF in a direction tilted slightly among light rays emitted from the light-emitting element LD.

As a ratio of the light rays converted in the third direction DR3 (in the frontal direction) among the light rays that are incident on the first layer HRF in a direction tilted slightly is increased, a white angular dependency (“WAD”) phenomenon may be reduced, so that the reliability of the display device may be enhanced.

As heights of the first to third partition walls LRF_R to LRF_B onto which the light rays that are incident on the first layer HRF in a direction tilted slightly are increased, the ratio of light rays converted in the third direction DR3 (in the frontal direction) may be increased.

Under conditions in which the refractive index of the first partition wall LRF_R is 1.5 and the refractive index of the first layer HRF is about 1.8, a rate of a front luminance as a function of the increase in height of the first partition wall LRF_R has been measured. Table 1 illustrates the rate of the front luminance as a function of the increase in height of the partition wall on the assumption that the front luminance is 100% in case that the thickness of the partition wall is 0 micrometer (μm).

TABLE 1

| Thickness of partition wall (unit: μm) | Rate of front luminance |
|---|---|
| 0 | 100% |
| 2.0 | 104% |
| 2.5 | 106% |
| 3.0 | 108% |

Referring to Table 1, as the heights of the first to third partition walls LRF_R to LRF_B are increased, the rate of the front luminance may be increased. Under conditions in which the refractive index of the first partition wall LRF_R is 1.48 and the refractive index of the first layer HRF is 1.63, a rate of a side luminance to the front luminance as a function of the height of the first partition wall LRF_R has been measured. Table 2 illustrates the rate of the side luminance as a function of the increase in height of the partition wall on the assumption that the frontal surface luminance is 100%.

[ [symbol] 2]

| | Rate of front | Rate of front |
|---|---|---|
| Luminance | luminance in | luminance in |
| measuring | case that | case that |
| angle | height of | height of |
| (unit: | partition wall | partition wall |
| degree, °) | is 0 μm | is 3 μm |
| 0° | 100% | 100% |
| 45° | 43% | 32% |
| 60° | 19% | 11% |

Referring to Table 2, as the heights of the first to third partition walls LRF_R to LRF_B are increased, the rate of the side luminance may be reduced. In other words, as the heights of the first to third partition walls LRF_R to LRF_B are increased, the ratio of light rays converted in the third direction DR3 (in the frontal direction) among light rays that are incident on the first layer HRF in a direction tilted slightly is increased, so that the rate of the side luminance may be reduced. The ratio of light rays converted in the third direction DR3 (in the frontal direction) among the light rays that are incident on the first layer HRF in a direction tilted slightly may be changed depending on the wavelength (or the color) of light emitted from the light-emitting element LD. Experimentally, as the wavelength of light emitted from the light-emitting element LD is increased, the ratio of light rays converted in the third direction DR3 (in the frontal direction) among the light rays that are incident on the first layer HRF in a direction tilted slightly may be reduced.

Therefore, to provide uniform luminance, the ratio of light rays converted in the third direction DR3 (or the frontal direction) among the light rays that are incident on the first layer HRF in a direction tilted slightly is desired to be maintained constant regardless of the wavelength of light emitted from the light-emitting element LD.

The pixels PXL_R to PXL_B in an embodiment of the disclosure may include partition walls LRF_R to LRF_B having different heights depending on the colors of light emitted from the respective pixels PXL_R to PXL_B.

In an embodiment, the first pixel PXL_R configured to emit a first color of light may include a first partition wall LRF_R having a first height H_R. The second pixel PXL_G configured to emit light having a second color different from the first color may include a second partition wall LRF_G having a second height H_G different from the first height H_R. The third pixel PXL_B configured to emit light having a third color different from the first color or the second color may include a third partition wall LRF_B having a third height H_B different from the first height H_R or the second height H_G.

In an embodiment, in the case where the wavelength of light emitted from the first pixel PXL_R is longer than that of light emitted from the second or third pixel PXL_G or PXL_B, the first height H_R of the first partition wall LRF_R may be greater than the second height H_G or the third height H_B. In an embodiment, in the case where the first pixel PXL_R is a red pixel, the second pixel PXL_G is a green pixel, and the third pixel PXL_B is a blue pixel, a ratio of the first to third heights H_R, H_G, and H_B may be 1:0.3:0.3, for example.

In an embodiment, each of the first to third partition walls LRF_R to LRF_B may include at least one dye. The at least one dye included in each of the first to third partition walls LRF_R to LRF_B may absorb light having a wavelength band ranging from approximately 380 nm to approximately 430 nm. In an embodiment, the at least one dye may include pigment yellow 139, for example. In the case where the light rays that are incident on the first layer HRF in a direction tilted slightly is irradiated onto the first to third partition walls LRF_R to LRF_B, some light rays may be absorbed to the first to third partition walls LRF_R to LRF_B. In another embodiment, in the case where the first pixel PXL_R is a red pixel, the second pixel PXL_G is a green pixel, and the third pixel PXL_B is a blue pixel, only the third partition wall LRF_B may include at least one dye. The at least one dye included in the third partition wall LRF_B may be dye capable of absorbing light in a blue wavelength band. Therefore, in the case where the light rays that are incident on the first layer HRF in a direction tilted slightly is irradiated onto the third partition wall LRF_B, some light rays may be absorbed to the third partition wall LRF_B. A rate at which blue color light is generated from the side surface of the third pixel PXL_B may be reduced.

In the first to third pixels PXL_R to PXL_B configured to emit different colors of light from each other in the display device according to the disclosure, a ratio of light rays converted in the third direction DR3 (or the frontal direction) among light rays generated from the light-emitting element LD may remain constant, and a WAD phenomenon resulting from variation in side visual angle may be mitigated (or minimized).

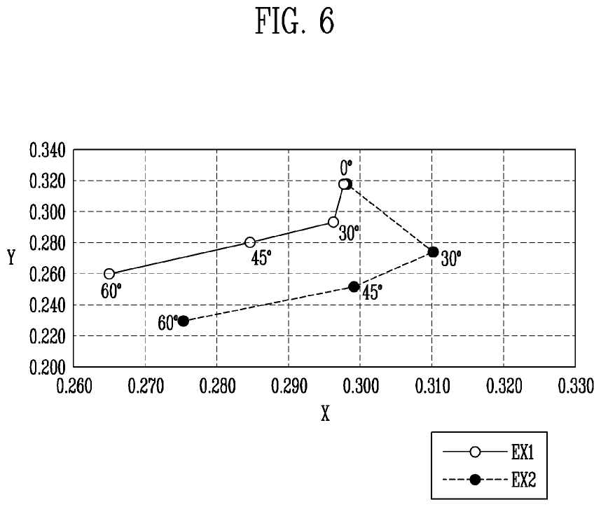

FIG. 6 is a graph showing movement of color coordinates as a function of a visual angle in accordance with a comparative example and an embodiment of the disclosure.

FIG. 6 illustrates movement of color coordinates as a function of a visual angle in a first Embodiment EX1 and a second Example EX2. The first Embodiment EX1 may refer to an embodiment of the disclosure, and shows movement of color coordinates as a function of a visual angle in the case where the first pixel PXL_R included in the display device is a red pixel and includes the first partition wall LRF_R having the first height H_R. The second Example EX2 may refer to a comparative example, and shows movement of color coordinates as a function of a visual angle in the case where a pixel included in the display device is a red pixel and does not include a partition wall.

Referring to FIG. 6, as the visual angle of the display device increases (as a side visual angle increases), the color coordinates tends to move toward the lower right-hand corner and then moves toward the lower left-hand corner. As the visual angle moves to 30°, the second Example EX2 moves toward the lower right-hand corner by a larger distance than is the first Embodiment EX1. In the display device according to the second Example EX2, when viewed sideways, an image is reddish compared to when viewed in the front. In the first Embodiment EX1, a displacement of the color coordinates as a function of the increase in the visual angle is relatively small. Hence, in the display device according to the first Embodiment EX1, a phenomenon in which an image when viewed sideways is reddish compared to when viewed in the front may be mitigated.

FIG. 7 is a schematic cross-sectional view of the display device DD (or the display panel DP) of FIG. 2B.

Referring to FIG. 7, except the components of the input sensing layer ISL illustrated in FIG. 5, the other components are the same as or correspond to those illustrated in FIG. 5, and therefore, the same reference numerals will be used to designate the same or corresponding components, and redundant explanation thereof will be omitted.

Referring to FIG. 7, the reflection adjusting layer RAL may be disposed on the display element layer LDL. The light-blocking component BM and the first to third partition walls LRF_R to LRF_B may be provided and/or formed on the second inorganic layer IOL2.

In the display device in embodiments of the disclosure, the pixels configured to emit different colors of light from each other may respectively include partition walls having different heights, so that a rate of the luminance of light emitted in the frontal direction may be maintained uniform, and the WAD phenomenon resulting from variation in side visual angle may be mitigated. Therefore, embodiments of the disclosure may provide a display device having relatively high reliability.

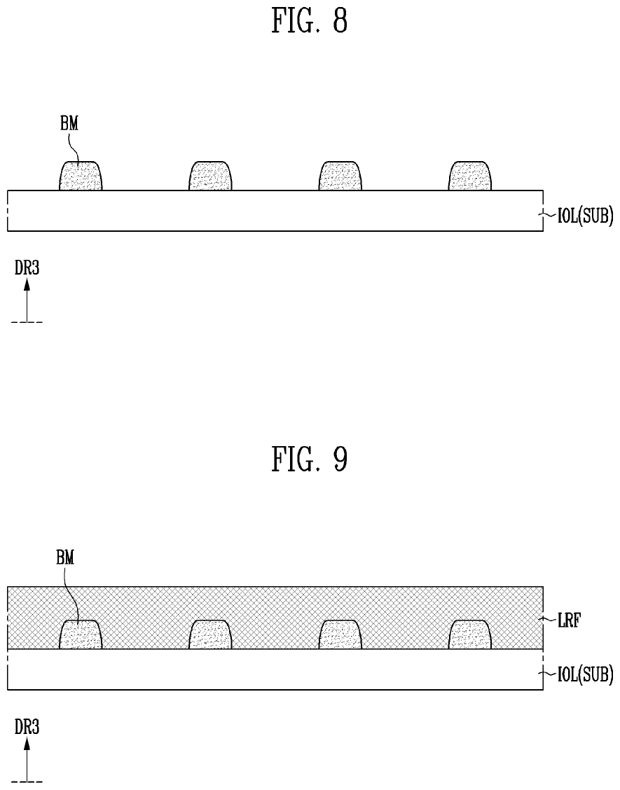

FIGS. 8 to 12 are cross-sectional views schematically illustrating a method of fabricating the display device in embodiments of the disclosure. A method of fabricating the reflection adjusting layer (e.g., the reflection adjusting layer RAL of FIGS. 2A and 2B) will be mainly described with reference to FIGS. 8 to 12. Description overlapping that of the embodiments described above will be simplified, or may not be repeated.

Referring to FIG. 8, the light-blocking components BM may be formed on the substrate SUB (or the inorganic layer IOL). The light-blocking components BM may be formed at positions spaced apart from each other by a regular distance.

Referring to FIG. 9, a first organic layer LRF may be formed on the light-blocking component BM. The first organic layer LRF may be a component for forming the first to third partition walls LRF_R to LRF_B. During a subsequent process, the first to third partition walls LRF_R to LRF_B may be provided by etching the first organic layer LRF. In an embodiment, the first organic layer LRF may include or consist of an organic layer. The organic layer may include at least one of acryl resin, epoxy resin, phenolic resin, polyamide resin, and polyimide resin.

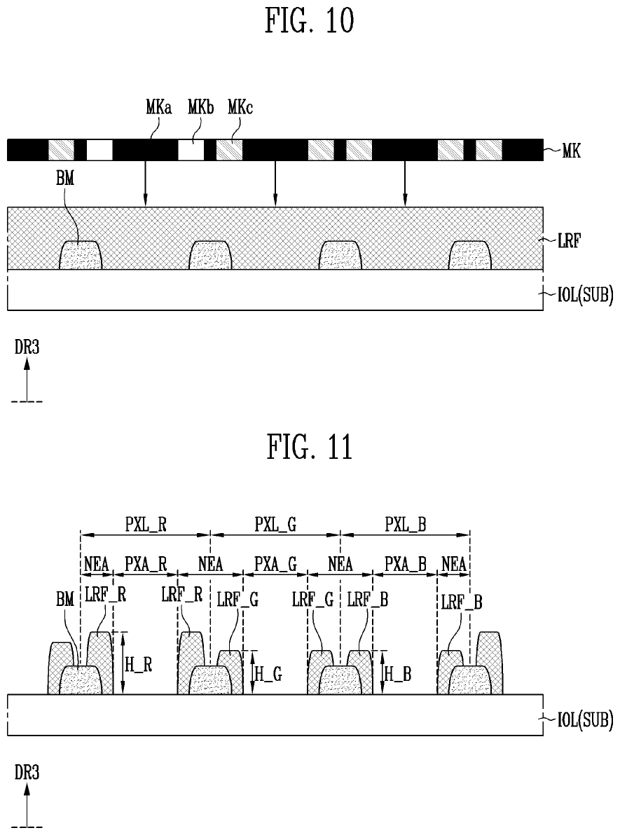

Referring to FIG. 10, the mask MK may be disposed on the first organic layer LRF. The mask MK may adjust rates of exposure applied to the first organic layer LRF by areas. A second area MKb of the mask MK may be adjusted such that a rate of exposure applied to the first organic layer LRF through the second area MKb is higher than that of the first area MKa or the third area MKc. A second area MKb of the mask MK may be adjusted such that a rate of exposure applied to the first organic layer LRF through the second area MKb is higher than that of a first area MKa or a third area MKc. In an embodiment, the first area MKa of the mask MK may block light to prevent a corresponding portion of the first organic layer LRF from being exposed. In an embodiment, the mask MK may be a half-tone mask or a slit mask.

Referring to FIGS. 10 and 11, the first organic layer LRF may be exposed at different exposure rates by areas through the mask MK. A portion of the first organic layer LRF may be removed through a developing process. Because rates at which portions of the first organic layer LRF are removed are different from each other depending on the exposure rates, the first to third partition walls LRF_R to LRF_B having different heights by areas may be formed through a single process.

The first partition wall LRF_R having the first height H_R may be formed by removing a portion of the first organic layer LRF that corresponds to the second area MKb of the mask MK. The second partition wall LRF_G having the second height H_G and the third partition wall LRF_B having the third height H_B may be formed by removing portions of the first organic layer LRF that correspond to the third area MKc of the mask MK. In an embodiment, the first height H_R may be greater than the second height H_G or the third height H_B.

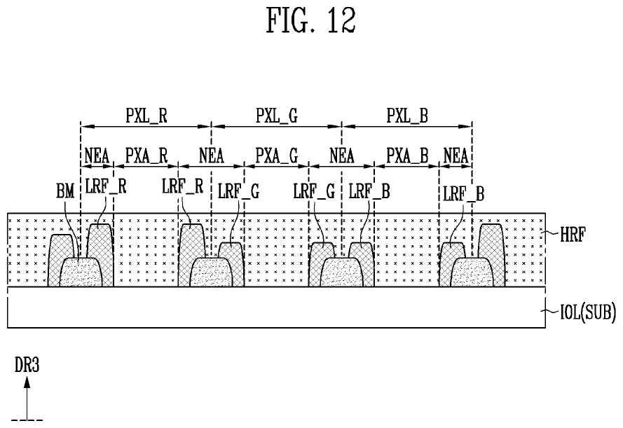

Referring to FIG. 12, a second organic layer HRF (or the first layer HRF) may be formed to cover the overall surfaces of the light-blocking component BM and the first to third partition walls LRF_R to LRF_B.

In an embodiment, the second organic layer HRF may include or consist of an organic layer including organic material having a refractive index higher than that of the first to third partition walls LRF_R to LRF_B. In an embodiment, due to a refractive index difference (or a refractive index ratio) between the first to third partition walls LRF_R to LRF_B and the second organic layer HRF, light rays that are incident on the second organic layer HRF in a direction tilted slightly may be irradiated onto the first to third partition walls LRF_R to LRF_B, and may be reflected by the first to third partition walls LRF_R to LRF_B and then re-incident on the second organic layer HRF.

In a display device in embodiments of the disclosure, pixels configured to emit different colors of light from each other may respectively include partition walls having different heights, so that a rate of luminance of light emitted in a frontal direction may be maintained uniform, and a WAD phenomenon resulting from variation in side visual angle may be mitigated. Therefore, embodiments of the disclosure may provide a display device having relatively high reliability.

However, effects of the disclosure are not limited to the above-described effects, and various modifications are possible without departing from the spirit and scope of the disclosure.

While embodiments of the disclosure have been described above, those skilled in the art will appreciate that various modifications, additions and substitutions are possible, without departing from the scope and spirit of the disclosure claimed in the appended claims.

What is claimed is:

1. A display device comprising:
a first pixel including a first emission area which emits light having a first color in a third direction;
a second pixel including a second emission area which emits light having a second color different from the first color;
a first partition wall in which a first opening overlapping the first emission area in a plan view is defined;
a second partition wall in which a second opening overlapping the second emission area in the plan view is defined; and
a first layer covering the first partition wall and the second partition wall,
wherein the first partition wall is provided with a first height in the third direction, and the second partition wall is provided with a second height different from the first height.

2. The display device according to claim 1,
wherein the light of the first color includes red light,
wherein the light of the second color includes green light or blue light, and
wherein the first height of the first partition wall is greater than the second height of the second partition wall.

3. The display device according to claim 2, wherein a ratio of the first height of the first partition wall and the second height of the second partition wall is about 1:0.3.

4. The display device according to claim 1,
wherein each of the first partition wall and the second partition wall includes a first refractive index, and
wherein the first layer includes a second refractive index higher than the first refractive index.

5. The display device according to claim 1, further comprising a light-blocking component which defines a non-emission area between the first emission area and the second emission area,
wherein the first partition wall and the second partition wall are disposed in a same layer as the light-blocking component.

6. The display device according to claim 5, wherein, in the plan view, a portion of the first partition wall directly contacts a first side of the light-blocking component, and a portion of the second partition wall directly contacts a second side of the light-blocking component.

7. The display device according to claim 5, wherein the light-blocking component, the first partition wall, and the second partition wall are integrally disposed.

8. The display device according to claim 5,
wherein each of the first pixel and the second pixel comprises:
a light-emitting element;
a transistor configured to control current of the light-emitting element; and
a first inorganic layer covering the light-emitting element,
wherein the light-emitting element comprises:
a first electrode;
an emission layer disposed on the first electrode; and
a second electrode disposed on the emission layer, and
wherein the first partition wall and the second partition wall are disposed on the first inorganic layer.

9. The display device according to claim 8, further comprising a pixel defining layer disposed between the light-emitting element of the first pixel and the light-emitting element of the second pixel,
wherein in the plan view the pixel defining layer overlaps the light-blocking component.

10. The display device according to claim 8, further comprising:
an organic layer directly disposed on the first inorganic layer; and
a second inorganic layer directly disposed on the organic layer,
wherein the first partition wall and the second partition wall are directly disposed on the second inorganic layer.

11. The display device according to claim 8, further comprising
an organic layer directly disposed on the first inorganic layer;
a second inorganic layer and a third inorganic layer successively disposed on the organic layer; and
a sensing electrode disposed on the second inorganic layer and overlapping the non-emission area in the plan view,
wherein the first partition wall and the second partition wall are directly disposed on the third inorganic layer.

12. The display device according to claim 1, further comprising:
a third pixel including a third emission area which emits, in the third direction, light having a third color different from the first color or the second color; and
a third partition wall in which a third opening overlapping the third emission area in the plan view is defined,
wherein the light of the first color includes red light, the light of the second color includes green light, and the light of the third color includes blue light, and
wherein the third partition wall is provided with a third height different from the first height.

13. The display device according to claim 12, wherein the first height, the second height, and the third height are different from each other.

14. The display device according to claim 12, wherein the third partition wall includes dye capable of absorbing light in a wavelength band ranging from about 380 nanometers to about 430 nanometers.

15. The display device according to claim 1,
wherein the first layer includes at least one dye, and
wherein a maximum absorption wavelength of the first layer ranges from about 530 nanometers to about 600 nanometers.

16. The display device according to claim 15, wherein the at least one dye includes at least one of tetraazaporphyrin, porphyrin, oxazine, squarylium, polymethine, triarylmethane, anthraquinone, phtalocyanine, azo, perylene, xanthene, diimmonium, and dipyrromethene.

17. A method of fabricating a display device, the method comprising:
disposing a light-blocking component on a substrate;
forming a first organic layer on the light-blocking component;
removing a portion of the first organic layer, and forming a first partition wall having a first height and a second partition wall having a second height different from the first height; and
forming a second organic layer covering the light-blocking component, the first partition wall, and the second partition wall.

18. The method according to claim 17, wherein removing the portion of the first organic layer comprises exposing and developing the first organic layer using a half-tone mask, and forming the first partition wall and the second partition wall.

19. The method according to claim 18,
wherein a portion of the first organic layer which corresponds to a first area of the half-tone mask is provided as the first partition wall, and a portion of the first organic layer which corresponds to a second area of the half-tone mask is provided as the second partition wall, and
wherein a transmittance of the first area is higher than a transmittance of the second area.

20. The method according to claim 19, wherein a height of the first partition wall is greater than a height of the second partition wall.
